(19) United States
(12) Patent Application Publication
(10) Pub. No.: US 2021/0339652 A1
(43) Pub. Date: Nov. 4, 2021

(54) METHOD FOR MONITORING AN ENERGY STORE IN A VEHICLE ELECTRICAL SYSTEM

(71) Applicant: Robert Bosch GmbH, Stuttgart (DE)

(72) Inventors: Frederic Heidinger, Esslingen (DE); Juergen Motz, Steinheim An Der Murr (DE); Oliver Dieter Koller, Weinstadt (DE)

(21) Appl. No.: 17/274,332

(22) PCT Filed: Nov. 20, 2019
(86) PCT No.: PCT/EP2019/081943

§ 371 Date: Mar. 8, 2021

(30) Foreign Application Priority Data
Nov. 28, 2018 (DE) 10 2018 220 494.2

(51) Int. Cl. B60L 58/16; B60L 58/12; G01R 31/392; G01R 31/389; G06Q 10/04; G06Q 50/06; G01R 31/3832

(52) U.S. Cl. CPC B60L 58/16; B60L 58/12; G01R 31/392; B60L 2260/50; G06Q 10/04; G06Q 50/06; G01R 31/3832; G01R 31/389

(57) ABSTRACT

A method for monitoring an energy store in an on-board electrical system of a motor vehicle. At least one instantaneous parameter of the energy store is determined, and this at least one parameter is forwarded to a forecast model. The forecast model determines future values for the at least one parameter from the instantaneous value for the at least one parameter. The future value of the at least one parameter is provided to a voltage predictor which calculates a minimum voltage of the energy store to be expected for a selected function.

### FIELD

The present invention relates to a method for monitoring an energy store in a vehicle electrical system of a motor vehicle, and to a system for carrying out the method.

### BACKGROUND INFORMATION

In automotive use, a vehicle electrical system shall be understood to mean the entirety of all electrical components in a motor vehicle. This encompasses both electrical consumers and supply sources, such as for example batteries. A distinction is made in the process between the on-board power supply system and the on-board communication system, above all the on-board power supply system being addressed herein, which is responsible for supplying the components of the motor vehicle with power. A microcontroller is usually provided for controlling the vehicle electrical system, which in addition to control functions also carries out monitoring functions.

In a motor vehicle, care must be taken that electrical power is available in such a way that the motor vehicle may be started at any time and that sufficient power supply is ensured during operation. However, electrical consumers should still be operable for an adequate time period also in the parked state, without a subsequent start being impaired.

The vehicle electrical system has the task of supplying the electrical consumers with power. If the power supply fails in today's vehicles due to an error or aging in the vehicle electrical system or in a vehicle electrical system component, important functions, such as the power steering system, are not available. Since the ability to steer the vehicle is not impaired, but only becomes difficult to carry out, the failure of the vehicle electrical system in today's series-produced vehicles is generally accepted since the driver is available as a fallback level.

The increasing electrification of power units as well as the introduction of new driving functions result in higher requirements with regard to the safety and reliability of the electrical power supply in the motor vehicle.

In future highly automated driving functions, such as for example an expressway pilot, the driver is permitted non-driving activities to a limited degree. From this it follows that the human driver is only able to perform the function as a sensory, control-technological, mechanical and energetic fallback level to a limited extent, or not at all, until the highly automated driving function has ended. The electrical supply thus has an unprecedented safety relevance in the motor vehicle during highly automated driving to ensure the sensory, control-technological and actuator-based fallback level. Errors or aging in the vehicle electrical system therefore must be identified reliably and preferably completely within the meaning of product safety.

To be able to forecast the failure of components, reliability-related approaches for monitoring vehicle components were developed. For this purpose, the vehicle electrical system components are monitored during operation, and their damage is ascertained.

German Patent Application No. DE 10 2013 203 661 A1 describes a method for operating a motor vehicle including a vehicle electrical system, which includes at least one semiconductor switch which undergoes loading during operation. In the method, an actual load of the semiconductor switch is ascertained based on past loading events.

The use of a battery sensor according to the related art is shown in FIG. 1. A method for determining the state of batteries is described in German Patent Application No. DE 10 2016 211 898 A1. In the process, methods from the reliability determination are used to describe the state of health of the battery. So-called load/capacity models are used in the process, which provide information about the probability of failure of the component.

A method for detecting a state of an energy store is described in German Patent Application No. DE 199 59 019 A1. The actual variables of the energy store are feedable to an estimation routine as well as, decoupled, both to a model-based parameter estimator and a filter. Obtained parameterization variables are fed to a predictor extrapolating the behavior of the energy store.

European Patent No. EP 1 231 476 B1 describes a method for determining the aging state of a battery. In the method, an open circuit voltage, an internal resistance, and an inner voltage drop are estimated and used as input variables of a model. This model is initialized and subsequently stimulated. With the aid of the model, the aging state is estimated.

### SUMMARY

In accordance with example embodiments of the present invention, a method for monitoring an energy store, for example a battery, in an on-board electrical system of a motor vehicle, and a system for carrying out the method are provided. Specific embodiments are derived from the disclosure herein.

The described method is used to monitor an energy store in an on-board electrical system of a motor vehicle. Hereafter, in particular the monitoring of a battery as an energy store in a vehicle electrical system is addressed. The described method, however, is not limited to the monitoring of a battery, but may also be employed with other energy stores, for example with capacitors, in particular high performance capacitors.

In the method, in one embodiment of the present invention, at least one parameter of a battery, for example an internal resistance, a capacitance and/or polarizations of the battery, is determined, and this at least one parameter is forwarded to a prediction model which calculates instantaneous values for the parameter and, via a load/capacity model, determines future values for the at least one parameter. The future value of the at least one parameter is provided to a voltage predictor, which calculates a minimum voltage of the battery to be expected for a selected function.

It has been shown that the terminal voltage at the consumer is decisive for the function of the safety-relevant consumers in the particular channel. This terminal voltage results from the transmission path including the voltage source, for example a battery or a DC-DC converter, wiring harness resistances in the corresponding sub-branches, as well as the combination of the load currents of the individual components.

It was furthermore recognized that a drop below the minimum supply voltage required for the particular operating case results in a failure of the corresponding component. This may cause a violation of safety targets in the safety-relevant scenario or limit the availability of automated driving functions.

Such a drop below the minimum supply voltage may arise due to the degradation of the energy store, for example of the battery. To counteract this and achieve a preferably high function availability, a predictive diagnostic function is required for the battery, based on which either predictive maintenance or measures in the vehicle electrical system energy management (predictive health management) is/are implemented.

The function- and boundary condition-based predictive failure forecast considerably increases the quality of the prediction compared to the conventional functions, since it is possible to predict under what conditions and when the battery is no longer able to sufficiently support the vehicle electrical system, and thus a failure occurs.

The method in accordance with an example embodiment of the present invention predicts the failure of the energy store, for example of the battery, based on its past use and the relevant system functions to take counter measures in a timely manner, whereby the function availability is increased.

The method in accordance with the present invention may have a number of advantages, at least in some of the embodiments:
increase in the function availability, e.g., start-stop and/or automated driving functions;
maintenance support, from which follows a maximization of the maintenance intervals, without creating additional failures, resulting in a maximization of the vehicle availability for fleet operators;
cost reduction due to the avoidance of broken-down vehicles, for example recovery costs, etc.;
increase in safety due to the avoidance of broken-down vehicles in unclear situations.

The system in accordance with an example embodiment of the present invention is used to carry out the method and may, for example, be used in connection with a battery sensor.

Further advantages and embodiments of the present invention are derived from the description herein and the figure.

It shall be understood that the above-mentioned features and those still to be described hereafter may be used not only in the particular described combination, but also in other combinations, or alone, without departing from the scope of the present invention.

### BRIEF DESCRIPTION OF THE DRAWINGS

FIG. 1 shows a battery sensor according to the related art in a block diagram.

FIG. 2 shows the equivalent circuit diagram of a battery.

FIG. 3 shows the procedure during the determination of the state of function (SOF).

FIG. 4 shows an execution of a method in a flowchart, in accordance with an example embodiment of the present invention.

### DETAILED DESCRIPTION OF EXAMPLE EMBODIMENTS

The present invention is schematically shown in the figures based on specific embodiments and is described in greater detail hereafter with reference to the figures.

The following specific embodiments describe the use of the presented method in connection with a battery. The presented method is not limited to these applications and may be carried out in connection with all suitable energy stores, for example in connection with capacitors, in particular with high performance capacitors, such as for example supercapacitors (supercaps) or ultracapacitors.

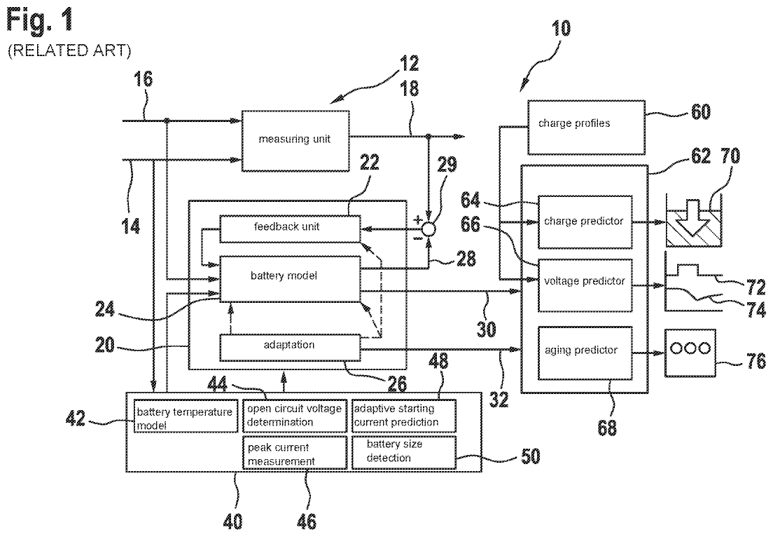

FIG. 1 shows a battery sensor according to the related art, which is denoted overall by reference numeral 10. Input variables in a unit 12, in particular a measuring unit, are temperature T 14 and current I 16, and the output variable is voltage U 18.

In a block 20, parameters and states are estimated. A feedback unit 22, a battery model 24 and an adaptation 26 of the parameters are provided therein. A variable û 28, state variables \hat{ }x 30 and model parameters \hat{ }p 32 are output.

A node 29 is used to adapt battery model 24 to the battery. Current I 16 is incorporated directly, and temperature T 14 is incorporated indirectly in battery model 24. This calculates û 28 and compares this to real voltage U 18. In case of deviations, battery model 24 is corrected with the aid of feedback unit 22.

Moreover, a block 40 for sub-algorithms is provided. This includes a battery temperature model 42, an open circuit voltage determination 44, a peak current measurement 46, an adaptive starting current prediction 48 and a battery size detection 50.

In addition, charge profiles 60 are provided, which are incorporated in a block 62 including predictors. These are a charge predictor 64, a voltage predictor 66 and an aging predictor 68. Outputs of block 62 are an SOC 70, curves of current 72 and voltage 74 and an SOH 76.

Battery sensor 10 thus ascertains instantaneous SOC (state of charge) 70 of the battery and instantaneous SOH 76 (state of health, loss of capacitance compared to the initial state) of the battery. With the aid of predictors 64, 66, 68, battery sensor 10 is able to predict SOC 70 and SOH 76 according to multiple previously defined loading scenarios. These may now also be adapted to automated driving or to the respective application.

Predictors 64, 66, 68 are furthermore able to simulate an engine starting process at the present battery state and to ascertain its effects on SOC 70, SOH 76 and the state of function (SOF). If the engine start during the simulation causes a drop below certain limiting values, the start-stop operation is blocked.

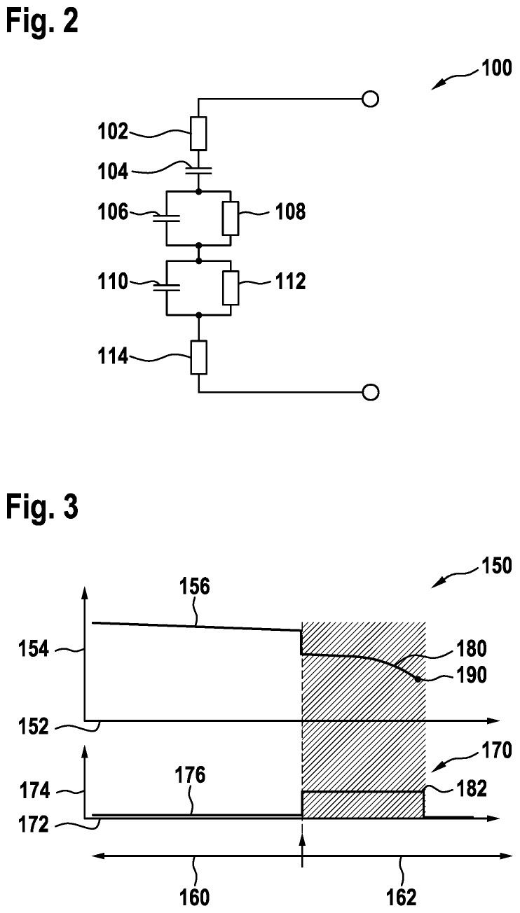

FIG. 2 shows the equivalent circuit diagram of a battery, which is denoted overall by reference numeral 100. This equivalent circuit diagram includes an internal resistance Rᵢ 102, a first capacitance C_{D} 104, a second capacitance Cₖ 106 in parallel to which a resistance Rₖ 108 is connected, a third capacitance C_{Dp} 110 in parallel to which a resistance R_{Dp} 112 is connected, as well as a further resistance R_{Dn} 114.

FIG. 3 shows the operating mode of the determination of the state of function. In a first graph 150, at whose abscissa 152 time t and at whose ordinate 154 voltage u(t) are plotted, a curve of voltage 156 for past 160 is plotted. In a second graph 170, at whose abscissa 172 time t and at whose ordinate 174 current i(t) are plotted, a curve of current 176 for past 160 is plotted. For future 162, a current curve 182 characteristic of a certain driving maneuver as well as a voltage curve 180 forecast or predicted by the predictor are plotted. Furthermore, a voltage U 190 is plotted, which represents the starting point for the calculation of the SOF. U 190 is typically the instantaneously measurable operating voltage, but it is also possible to use a theoretically expectable minimum voltage, which may be used for a worst case prediction. The characteristic current curve 182 represents a virtual current profile i(t) according to a platform or a customer specification, for example the battery current profile which results during an engine start, for the prediction of the battery voltage drop during the engine warm start for stop/start applications.

The minimum predicted voltage for a certain current profile i(t) is used as the state of function (SOF; measure of the performance capability of the battery for fulfilling a certain vehicle function, for example the warm start of the engine), and is used hereafter for the decision regarding the availability of a certain function.

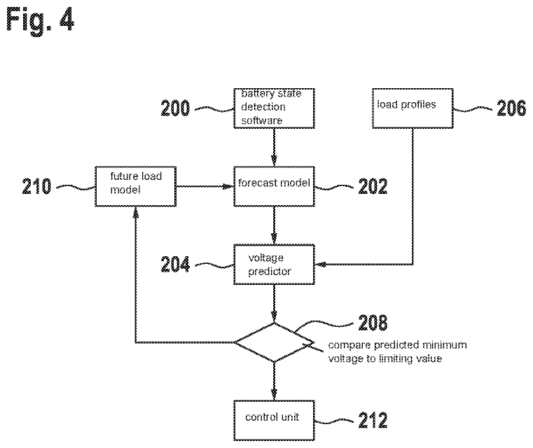

FIG. 4 shows the flowchart of an exemplary implementation of a method in accordance with an example embodiment of the presnt invention. In a first step, the instantaneous capacitance and the internal resistance of the battery are determined or measured in a battery state detection software 200. These are forwarded to a forecast model 202. With the aid of representative load collectives (RLC; future load profile of the battery to be expected) and with the aid of a load/capacity model, forecast model 202 calculates the future values of the capacitance (C_pred(t)) and of the internal resistance (Ri_pred(t)).

The forecast model may be based on a load/capacity model, a physical model, a machine learning-based model, on regression or on a spline extrapolation.

These values are forwarded to a voltage predictor 204. It calculates the minimum voltage of the battery to be expected for a given function with the aid of an electrical equivalent circuit diagram, as is illustrated, for example, in FIG. 2, analogously to the operating mode of the SOF. For this purpose, load profiles 206 for current I, starting voltage U, and temperature T are used. The predefined current profile may stem from arbitrary functions, for example from a start-stop or safe stop maneuver for automated driving.

In next step 208, the predicted minimum voltage (U_pred(t)) is compared to the limiting value, which, upon a shortfall, would cause the vehicle electrical system to fail. If this limiting value is reached or fallen short of, point in time t corresponds to the remaining useful life of the battery. Otherwise, time step t is increased by a Δt, and new representative load collectives (RLC) are calculated with the aid of the future load model 210. These representative load collectives are based, for example, on the past load of the battery in the form of changes in the charge state, the current, the voltage, the temperature, the ampere hour throughput etc., and map the future load of the battery to be expected. In the process, a distinction is also made, for example, between different boundary conditions, such as the season, the route, etc. These representative load collectives are then provided to the forecast model, and new values are determined for C_pred(t) and Ri_pred(t). This iteration is carried out until the predicted minimum voltage reaches the limiting value, and thus the remaining useful life (RUL) is determined. In the next step, this information is forwarded to a control unit 212, which derives measures therefrom, such as the predictive component replacement (predictive maintenance) or control measures for increasing the useful life (predictive health management).

The method, thus provides, for the creation of a diagnostic model of a battery. In one example embodiment of the present invention, at least one battery variable, for example the voltage, current or temperature, is measured via a sensor. These battery variables are transmitted to the battery state detection software (BSD) 200, which determines variables describing the battery state. In the process, BSD 200 may be based on physical, statistical or artificial intelligence (AI) models. The state-describing variables, such as for example the internal resistance of the battery, the capacitance, etc., are forwarded to forecast model 202.

In a further model, the battery variables may be classified over the time to form, for example, representative load collectives of the load of the battery. In addition, further signals of the battery or from the system may be used to form the representative load collectives. These RLCs are also transmitted to forecast model 202.

Based on the RLCs and the instantaneously determined state-describing variables of the battery, forecast model 202 predicts the future progression of the state-describing variables of the battery. In the process, the forecast model may also again be a physical, statistical or AI model.

The extrapolated state-describing battery variables are used in an evaluation model to determine the point in time of failure of the battery. This may essentially take place in two different ways. The first option compares the extrapolated state-describing battery variables to a limiting value or a limiting value distribution starting at which the battery is no longer functional. The second option uses the extrapolated state-describing battery variables to simulatively establish the remaining useful life (RUL). Similarly to the SOF function, as is illustrated in FIG. 3, it is established in the process, based on the state-describing battery variables and a load profile for different functions, whether the voltage at the battery drops below a threshold value. A drop below this threshold value results in a system failure.

As was described above, the method may be used to ascertain a remaining useful life of the battery. Based on the remaining useful life, a maintenance interval and/or a replacement of the battery may then be regulated. Based on the remaining useful life, it is also possible to take measures in the energy management to increase the remaining useful life. These measures may be selected from a suspension and/or degradation of functions of a change in the setpoint operating range of the battery or, in the case of multiple energy stores, a shift in the load between these energy stores.

1-15. (canceled)

16. A method for monitoring an energy store in an on-board electrical system of a motor vehicle, the method comprising the following steps:
determining an instantaneous value for at least one parameter of the energy store;
forwarding the instantaneous value to a forecast model;
determining, by the forecast model, a future value for the at least one parameter from the instantaneous value for the at least one parameter;
providing the future value of the at least one parameter to a voltage predictor; and
calculating, by the voltage predictor, a minimum voltage of the energy store to be expected for a selected function.

17. The method as recited in claim 16, wherein the forecast model is based on a load/capacity model, or a physical model, or a machine learning-based model, or a regression extrapolation, or a spline extrapolation.

18. The method as recited in claim 16, wherein the energy store is a battery, and a capacitance of the battery is determined as the parameter.

19. The method as recited in claim 16, wherein the energy store is a battery, and an internal resistance of the battery is determined as the parameter.

20. The method as recited in claim 16, wherein the energy store is a battery, and polarizations of the battery are determined as the parameter.

21. The method as recited in claim 16, wherein the forecast model is calculates the future value of the at least one parameter using a future estimated load.

22. The method as recited in claim 16, wherein the voltage predictor calculates the minimum voltage using an equivalent circuit diagram of the energy store.

23. The method as recited in claim 16, wherein load profiles for current, voltage and temperature are used during the calculation of the minimum voltage.

24. The method as recited in claim 16, wherein the calculated minimum voltage is compared to a limiting value.

25. The method as recited in claim 23, wherein it is ascertained via a limiting value shortfall whether it will still be possible in the future to carry out functions assigned to the used load profiles.

26. The method as recited in claim 16, wherein a remaining useful life of the energy store is ascertained.

27. The method as recited in claim 26, wherein a maintenance interval and/or a replacement of the energy store is regulated based on the remaining useful life.

28. The method as recited in claim 26, wherein measures in energy management for increasing the remaining useful life are taken based on the remaining useful life.

29. The method as recited in claim 28, wherein the measure includes:
suspending and/or degrading functions, or
changing a setpoint operating range of the energy store, or
shifting a load between energy stores.

30. A system for monitoring an energy store in an on-board electrical system of a motor vehicle, the system configured to:
determine an instantaneous value for at least one parameter of the energy store;
forward the instantaneous value to a forecast model;
determine, by the forecast model, a future value for the at least one parameter from the instantaneous value for the at least one parameter;
provide the future value of the at least one parameter to a voltage predictor; and
calculate, by the voltage predictor, a minimum voltage of the energy store to be expected for a selected function.
